(19) United States
(12) Patent Application Publication
(10) Pub. No.: US 2008/0054449 A1
(43) Pub. Date: Mar. 6, 2008

(54) SEMICONDUCTOR COMPONENT WITH COOLING APPARATUS

(75) Inventors: Franz Hirler, Isen (DE); Ralf Otremba, Kaufbeuren (DE); Xaver Schloegel, Sachsenkam (DE)

Correspondence Address: SCHWEGMAN, LUNDBERG & WOESSNER / INFINEON, P.O. BOX 2938, MINNEAPOLIS, MN, 55402, US

(73) Assignee: Infineon Technologies AG

(21) Appl. No.: 11/469,295

(22) Filed: Aug. 31, 2006

(51) Int. Cl. H01L 23/34

(52) U.S. Cl. 257/713

(57) ABSTRACT

Embodiments of apparatus, having a plastic structure, a semiconductor chip at least partially embedded in the structure; a heat sink at least partially embedded in the structure with a portion thereof projecting from the structure; and a bridge member, at least partially embedded in the structure and thermally coupling the semiconductor chip to the heat sink.

### TECHNICAL FIELD

The various embodiments described herein relate cooling of semiconductor components.

### BACKGROUND

With increasing miniaturization of semiconductor components that include a semiconductor chip positioned in a housing, dissipation of heat from the housing represents a concern. Cooling semiconductor components is accomplished by placing the semiconductor chip on a chip carrier with an electrically conductive or electrically insulated attachment and to position this chip carrier on a heat sink. This type of assembly is difficult, in particular for very small components such as SMD components

### BRIEF DESCRIPTION OF THE DRAWINGS

FIG. 1 shows a semiconductor component having a contact bridge and a heat sink, where part of the heat sink protrudes from the housing of the semiconductor component, in cross section;

FIG. 2 shows a semiconductor component having a contact bridge, part of which protrudes from the housing of the semiconductor component, in cross section;

FIG. 3 shows a semiconductor component having a semiconductor chip, part of which protrudes from the housing of the semiconductor component, in cross section;

FIG. 4 shows a semiconductor component having a chip carrier which is in the form of a heat sink, and part of which protrudes from the housing of the semiconductor component, in cross section;

FIG. 5a shows a semiconductor component wherein the semiconductor chip is in thermal contact with a chip carrier, where part of the chip carrier protrudes from the housing of the semiconductor component, in cross section;

FIG. 5b shows a semiconductor chip according to FIG. 5a in a cross-sectional side view; and

FIG. 5c shows a semiconductor chip according to FIGS. 5a and 5b in a different cross-sectional side view.

### DETAILED DESCRIPTION

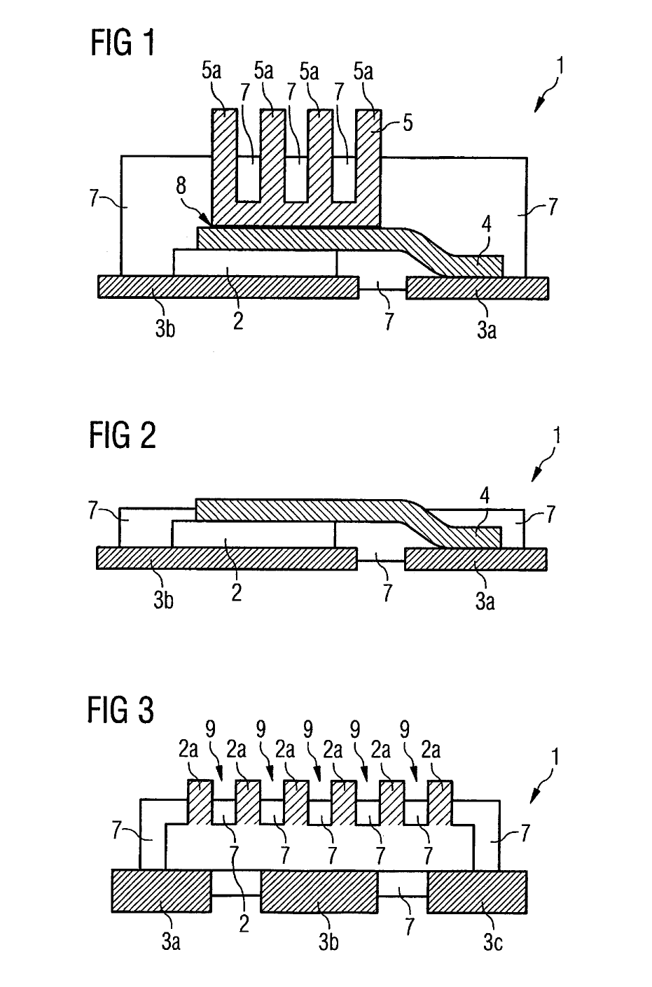

FIG. 1 shows a cross section through a semiconductor component 1 according to some embodiments of the invention. Semiconductor chip 2 is mounted on a chip carrier 3b, which likewise protrudes from the housing 7. In some embodiments the connection of this chip carrier 3b with the semiconductor chip 2 is conductive. In some embodiments it is electrically insulated.

In the embodiments shown in FIG. 1, chip carrier 3b and contact bridge 4 are attached to opposite sides of semiconductor chip 2. For cooling semiconductor chip 2 a heat sink 5 is provided, which is in thermal contact with contact bridge 4 and part of which protrudes from housing 7. Heat sink 5 protrudes from the housing on a side 7 which is opposite the side on which connecting lead 3a and chip carrier 3b are accessible from outside. If the connection of chip carrier 3b to semiconductor chip 2 is electrically conductive, this chip carrier 3b functions in addition to connecting lead 3a as an additional connecting contact for the component.

In some embodiments housing 7 is a cast substance or molding compound, and completely encloses semiconductor chip 2 and contact bridge 4, as well as partially enclosing heat sink 5, connecting lead 3a and chip carrier 3b.

In some embodiments heat sink 5 has a number of cooling ribs 5a which extend out of the housing 7, so as to give off part of the lost heat which accumulates in semiconductor chip 2 during operation of semiconductor component 1 to the environment, preferably air, of semiconductor component 1 through contact bridge 4 and heat sink 5.

In some embodiments, depending on the nature of component 1, the connection between contact bridge 4 and heat sink 5 is electrically conductive. In some embodiments, it is electrically insulated. If an electrically conductive connection is present between contact bridge 4 and heat sink 5, contact bridge 4 and heat sink 5, in some embodiments are formed in a single piece. In some embodiments they are bonded together by means of a thermally conductive glue.

Integrated into the semiconductor chip 2 is, in some embodiments, a power MOSFET or power IGBT, whose drain connection makes contact via chip carrier 3b and whose source connection makes contact via contact bridge 4. If the MOSFET or IGBT is to be placed in a circuit in which the source connection of the component has an electrical potential that differs only slightly or not at all from the ground potential, in some embodiments, the heat sink 5 has an electrically conductive connection with the semiconductor bridge 4, since no high electrical voltages are to be expected at heat sink 5 in this case, so that no special provisions need to be made in regard to insulating heat sink 5.

In some embodiments, if it is necessary in a semiconductor component 1 to isolate contact bridge 4 and heat sink 5 electrically from each other, this can be realized by an insulation layer 8 placed between contact bridge 4 and heat sink 5. In some embodiments, such an insulation layer 8 consists of an electrically insulating glue. In some embodiments, any organic (e.g. polyimide) and inorganic (e.g. metal oxide) coatings with good adhesion and insulating capability may be used.

Contact bridge 4 is, in some embodiments, made of a material with good thermal and electrical conductive properties. In some embodiments that material is one or mor materials selected from the group consisting of copper, aluminum or an alloy of these metals. Correspondingly, heat sink 5 is made of materials with at least good thermal conductive properties. In some embodiments, in addition to the metals and alloys already named, ceramic materials for example are also suitable here.

Another semiconductor component 1 according to some embodiments of the invention is shown in FIG. 2 in cross section.

This component, corresponding to the semiconductor component shown in FIG. 1, has a semiconductor chip 2 which is positioned on a housing 7 and a connecting lead 3a that extends out of the housing. With one of its connections, the semiconductor chip has an electrically conductive connection with connecting lead 3a by means of a contact bridge 4. Semiconductor chip 2 sits on a chip carrier 3b, contact bridge 4 and chip carrier 3b in some embodiments being positioned on opposite sides of semiconductor chip 2.

With one of its connections, semiconductor chip 2 has, in some embodiments, an electrically conductive connection with connecting lead 3a by means of a contact bridge 4.

At least part of contact bridge 4 protrudes from the housing 7 of semiconductor component 1. The contact bridge 4 is thus in thermal contact with the medium surrounding the semiconductor component, typically air. The lost heat that accumulates in the semiconductor chip 2 during operation of semiconductor component 1 can thus be removed via the contact bridge 4 to the surroundings of semiconductor component 1.

In some embodiments, contact bridge 4 is at the same electrical potential as connecting lead 3a. Semiconductor component 1 is therefore especially well suited, in some embodiments, for realizing power MOSFETs or power IGBTs, in which the connecting lead 3a constitutes the source connection, if the power MOSFET or power IGBT is placed in a circuit in which the source connection of the component is grounded.

Another semiconductor component 1 according to some embodiments of the invention is shown in FIG. 3. It has a semiconductor chip 2 that includes a section 2a which protrudes from the housing 7 of semiconductor component 1. Part of the lost heat that accumulates in the semiconductor chip 2 is thereby given off by the latter directly to the surroundings of semiconductor component 1, for example air.

To improve the cooling effect, in some embodiments, the semiconductor component 1 is structured. The form of the structuring is, in some embodiments, similar to the cooling ribs of a heat sink, in order to obtain the largest possible surface of the semiconductor chip 2, through which semiconductor component 1 is in thermal contact with its surroundings. In some embodiments, sections 2a of semiconductor chip 2 correspond to the cooling ribs of a heat sink in regard to form and function.

Sections 2a of semiconductor chip 2 are, in some embodiments, made of semiconductor material, and have one or more protective layers in order to prevent damage to the semiconductor chip 2, from penetrating moisture. Possibilities for protective layers in some embodiments, include oxide coatings, nitride coatings or metal plating. In some embodiments, organic coatings (such as polyimides or nanocomposites) are also be employed. If the top protective layer in particular is electrically conductive, it may, in some embodiments, be electrically insulated from the connections of the semiconductor chip. In some embodiments it is at the same electrical potential as one of the connections of the semiconductor chip 2.

Recesses 9 are formed between sections 2a of semiconductor chip 2, and, some embodiments, are partially filled on their side facing the semiconductor chip with a cast substance or molding compound. In some embodiments, the substance is the substance from which the housing 7 of the semiconductor component 1 is made.

On its side facing away from sections 2a, semiconductor chip 2 has connecting leads 3a, 3b and 3c. There may be in particular a MOSFET or an IGBT integrated into semiconductor chip 2, in which case the connecting leads 3a, 3b, 3c form the drain, source and gate connections of that MOSFET or IGBT. According to a preferred embodiment, sections 2a are of entirely metallic construction or have metal plating, and are at the drain potential of a p-channel or the source potential of an n-channel MOSFET or IGBT.

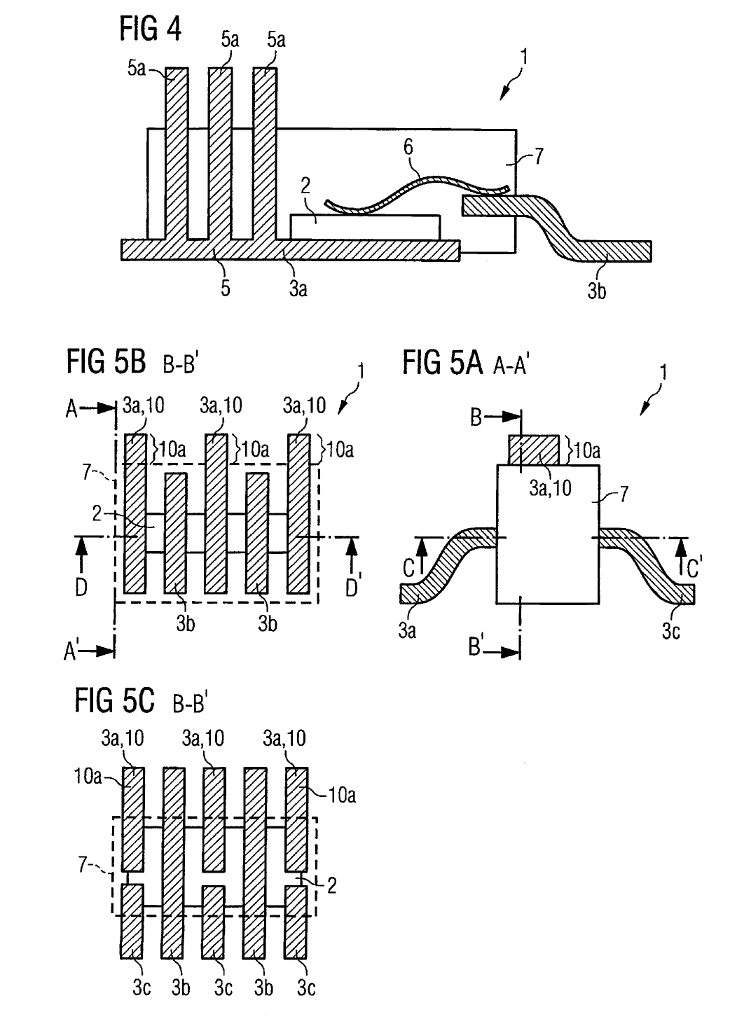

An additional possibility for efficient cooling of a semiconductor component is illustrated in some embodiments shown in FIG. 4. Semiconductor component 1 includes a semiconductor chip 2 which is placed on a housing 7, a connecting lead 3a protruding from the housing 7 which has an electrically conductive connection with semiconductor chip 2, and a chip carrier 3b on which semiconductor chip 2 is mounted. Semiconductor chip 2 is mounted on a section of chip carrier 3b which protrudes from housing 7 on a first side. Chip carrier 3b also includes a heat sink section 5 with cooling ribs 5a that extend through the housing 7, and which protrude from the housing 7 on a side thereof opposite the first side. In the example, the cooling ribs 5a run perpendicular to the carrier section on which semiconductor chip 2 is mounted.

Housing 7 is, in some embodiments, made of a cast substance or molding compound, and completely surrounds the semiconductor chip 2, as well as partially surrounding the connecting lead 3a and the chip carrier 3b with the cooling ribs 5a. In some embodiments, the space between the cooling ribs 5a is partially filled with molding compound. The cooling ribs 5a elevate the surface of the chip carrier 3b, which like the connecting lead 3a can serve to make conduct for the semiconductor chip and which has an electrically conductive connection with semiconductor chip 2 for that purpose.

FIGS. 5a, 5b and 5c show some embodiments of a semiconductor component 1, in which a semiconductor chip 2 is positioned on a chip carrier 3b and is thermally coupled with it. Along with its function carrying the semiconductor chip 2, chip carrier 3b also assumes a cooling function to dissipate lost heat to the environment of semiconductor component 1.

FIG. 5a presents a side view of semiconductor component 1 from the plane A-A′ shown in FIG. 5b, FIG. 5b shows a cross section in a plane B-B′ shown in FIG. 5a, and FIG. 5c shows a horizontal section through plane C-C′ from FIG. 5a and through plane D-D′ from FIG. 5b.

Chip carrier 10 is in the form of a connecting lead 3a, has an electrically conductive link to a connection of semiconductor chip 2, which in some embodiments is a load connection, and has sections 10a which protrude from housing 7 of semiconductor component 1 and serve to give off lost heat that accumulates in the semiconductor chip 2 to the medium surrounding the semiconductor component 1, in particular air.

Two other connecting leads 3b and 3c are designed, in some embodiments, as an additional load connection or as a control connection. If semiconductor component 1 is designedm in some embodiments, as an n-channel MOSFET or IGBT, then in the case of an n-channel MOSFET or IGBT chip carrier 10 and connecting lead 3a are, in some embodiments, electrically connected to the latter's source connection; in the case of a p-channel MOSFET or IGBT they are, in some embodiments, electrically connected to the drain connection of semiconductor chip 2.

With all semiconductor components 1 according to some embodiments of the invention, it is advantageous if a component that dissipates the lost heat from the semiconductor chip 2 to the medium surrounding the semiconductor component 1, in some embodiments, a heat sink 5, a contact bridge 4 or the metal plating 2a of a semiconductor chip 2, has an electrically conductive connection to the lower of the electrical potentials of the load connections of the semiconductor component 1. In some embodiments having typical circuit arrangements of MOSFETs or IGBTs, in some embodiments having n-channel models, the source connection has the lowest load potential. In embodiments having in p-channels, the drain connection has the lowest load potential.

Each of the connecting leads 3a, 3b and 3c, shown in some embodiments, can have any desired shape in all semiconductor components 1 according to the invention, for example peg-shaped, pin-shaped, flat, straight or curved.

The accompanying drawings that form a part hereof show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

1. Apparatus, comprising
a plastic structure
a semiconductor chip at least partially embedded in the structure;
a heat sink at least partially embedded in the structure with a portion thereof proj ecting from the structure; and
a bridge member, at least partially embedded in the structure and thermally coupling the semiconductor chip to the heat sink.

2. Apparatus according to claim 1, wherein the bridge member and the heat sink are electrically connected to each other.

3. Apparatus according to claim 1, wherein the contact bridge and the heat sink are electrically insulated from each other.

4. Apparatus according to claim 1, wherein the bridge and the heat sink comprise a unitary structure.

5. Apparatus according to claim 1, wherein at least part of the contact bridge is positioned between the semiconductor chip and the heat sink.

6. Apparatus according to claim 1, wherein at least part of the heat sink has cooling ribs projecting from the package.

7. Apparatus according claim 1 wherein the semiconductor chip is mounted on a chip carrier at least a portion of which protrudes from the housing.

8. Apparatus according to claim 1, wherein the contact bridge (4) and the chip carrier (3b) are positioned on opposite sides of the semiconductor chip (2).

9. Apparatus, comprising:
a housing;
a semiconductor chip, at least partially enclosed within the housing;
a connecting lead protruding from the housing; and
a contact bridge at least partially enclosed within the housing and a section of which protrudes from the housing, the contact bridge electrically coupling the connecting lead and the semiconductor chip.

10. Apparatus according to claim 9, wherein at least part of the section of the contact bridge that protrudes from the housing has a flat shape.

11. Apparatus according to one of claim 9, wherein the semiconductor chip is mounted on a chip carrier which protrudes from the housing.

12. Apparatus according to claim 11, wherein the chip carrier and the contact bridge are positioned on opposite sides of the semiconductor chip.

13. Apparatus having a housing enclosing a semiconductor chip, which has at least one contact section coupled to the chip and protruding from the housing.

14. Apparatus according to claim 13, wherein the at least one section that protrudes from the housing has metal plating.

15. Apparatus according to claim 12, wherein the semiconductor chip is designed as an SMD semiconductor element.

16. Apparatus, comprising
a substance filled housing;
a semiconductor chip at least partially embedded in the housing;
a heat sink at least partially embedded in the housing with a portion thereof proj ecting from the housing; and
a bridge member, at least partially embedded in the housing and thermally coupling the semiconductor chip to the heat sink.

17. Apparatus having a housing enclosing a semiconductor chip, which has at least one contact section coupled to the chip and protruding from the housing, a bridge structure coupled to the at least one contact section, and a heat sink thermally coupled to the bridge structure at least partially protruding from the housing.
